(19) United States
(12) Patent Application Publication
(10) Pub. No.: US 2026/0206189 A1
(43) Pub. Date: Jul. 16, 2026

(54) MULTISTAGE HIGH-EFFICIENCY COOLING SYSTEM

(71) Applicant: ThermalWorks, LLC, Darien, CT (US)

(72) Inventors: John M. Costakis, Saugerties, NY (US); Doron Shapiro, St. Louis, MO (US); Ming Zhang, Naples, FL (US); Paul Tarangelo, Lagrangeville, NY (US)

(73) Assignee: ThermalWorks, LLC, Darien, CT (US)

(21) Appl. No.: 19/445,360

(22) Filed: Jan. 9, 2026

Related U.S. Application Data
(60) Provisional application No. 63/744,176, filed on Jan. 11, 2025.

(51) Int. Cl. H05K 7/20; F25B 1/00; F25B 41/22; F25B 41/31

(52) U.S. Cl. CPC H05K 7/20718; F25B 1/00; F25B 41/22; F25B 41/31; H05K 7/20763; F25B 2700/19; F25B 2700/21

(57) ABSTRACT

A multistage high-efficiency cooling system provides coolant to both a coolant distribution unit fluidically coupled to liquid-cooled components and an air-cooling component located proximate to air-cooled components via a zone chiller. Depending on a percentage of air-cooled components versus liquid-cooled components within the system, and optionally ambient temperature, the system determines whether to adjust the temperature for the coolant provided to the air-cooling component. In one instance, the outdoor chiller provides the coolant to both the coolant distribution unit and the air-cooling component at a first temperature for operation of the cooling distribution unit, and the zone chiller adjusts the first temperature of the coolant to a different second temperature for the air-cooling component. Alternatively, the outdoor chiller provides the coolant to both the coolant distribution unit and the air-cooling component at the temperature required for operation of the air-cooling component, without substantial adjustment of temperature by the zone chiller.

### CROSS-REFERENCE TO RELATED APPLICATION

The present application claims the benefit of priority under 35 U.S.C. § 119(e) to U.S. Provisional Patent Application No. 63/744,176 , filed on Jan. 11, 2025, the entirety of which is incorporated herein by reference.

### FIELD OF THE INVENTION

The present invention is related generally to cooling systems and more specifically to a controllable multistage high-efficiency cooling system.

### BACKGROUND

The background description includes information that may be useful in understanding the present inventive subject matter. It is not an admission that any of the information provided herein is prior art or relevant to the presently claimed disclosure, or that any publication specifically or implicitly referenced is prior art.

In data centers, components (e.g., servers, server racks, server cabinets, etc.) may be cooled by air or another gas. For example, air may be circulated at a first lower temperature around the components, with heat transferring from the components to the air such that the air increases to a second higher temperature.

Alternatively or in addition, components (e.g., servers, server racks, server cabinets, etc.) may be cooled by a liquid coolant including water, a glycol (e.g., ethylene glycol, propylene glycol, etc.), a water-glycol mixture, or another liquid capable of cooling. For example, liquid coolant is circulated at a first lower temperature into the components, with heat transferring from the components to the liquid coolant such that the liquid coolant increases to a second higher temperature prior to exiting the components. Using liquid cooling allows for an increased cooling capacity in a more efficient manner for a higher server density, and with reduced energy consumption and lower operating costs. Liquid cooling can be used either alone or in combination with air cooling.

Elements such as outdoor chillers (e.g., rooftop chillers, etc.) may be employed by the data centers to cool the liquid coolant during circulation through the data centers, where a hotter liquid coolant is received by the outdoor chillers and a cooler liquid coolant is supplied by the outdoor chillers. With liquid-cooled components, the cooler liquid coolant may be directly supplied to the liquid-cooled components or alternatively may be supplied to coolant distribution units (CDUs) that circulates a secondary coolant (e.g., water, a glycol, a water-glycol mixture, or another liquid capable of cooling) through the liquid-cooled components. With air-cooled components, however, the liquid coolant may pass through an intermediate air-cooling component including, but not limited to, a computer room air conditioner (CRAC) that adjusts the temperature of air around the air-cooled components.

### SUMMARY

Often, liquid coolant used for liquid-cooled components has a different range of operating temperatures than the liquid coolant used in air-cooling components. Where data centers include only liquid-cooled components or air-cooling components, the liquid coolant circulated through the outdoor chillers may be kept at a single range of operating temperatures on the supply side. Where data centers include both liquid-cooled and air-cooling components, however, one option is to operate the outdoor chillers to circulate coolant at a single operating temperature on the supply side within an overlap of respective ranges of operating temperatures. For example, where the air-cooling components require a liquid coolant with a lower temperature than the liquid-cooled components, but where the liquid-cooled components can also utilize the lower-temperature liquid coolant, the outdoor chillers can cool the circulating liquid coolant to the lower temperature for both the air-cooling components and the liquid-cooled components. However, this is cost-intensive, requiring additional power consumption by the outdoor chillers to cool the circulating coolant to the lower temperature for the entire supply side of the system.

Where data centers include both liquid-cooled and air-cooling components and the ranges of operating temperatures for the supplied liquid coolant to each do not sufficiently overlap, the liquid coolant may need to be maintained at two different ranges of operating temperatures. One option is to have isolated flow systems for the liquid-cooling liquid coolant and the air-cooling liquid coolant, including through separate outdoor chillers. However, this setup would require two complete sets of isolated liquid coolant return and supply lines (or four total sets of lines, if redundancy is installed for both the supply and return lines) for both the liquid-cooling liquid coolant and the air-cooling liquid coolant. As such, this option is expensive and increases the difficulty of retrofitting a pre-existing structure to become a data center.

As such, there exists a long-felt but unmet need for systems and methods directed to an improved cooling efficiency of data centers, including where both liquid-cooled and air-cooling components are installed within the data center. The systems and methods should be capable of circulating liquid coolant at an increased efficiency to and from the outdoor chillers, both at a first range of operating temperatures for liquid-cooled components and at a second range of operating temperatures for air-cooling components, to reduce power consumption. For example, indoor or zone chillers may be utilized to reduce the temperature of the liquid coolant circulated from the supply side of the outdoor chillers from the first range of operating temperatures to the second range of operating temperatures.

The systems and methods should be able to adjust the temperature of the liquid coolant on the supply side for the liquid-cooled components and air-cooling components, depending on operational parameters including percentage of liquid-cooling versus percentage of air-cooling utilized. In one non-limiting example, depending on the ambient environment temperature and the percentage of liquid-cooling versus percentage of air-cooling utilized, the systems and methods should be able to determine an optimization point for reduced (or lowest) power consumption by utilizing only free-cooling with the outdoor chillers. It is noted that this determination may take into consideration the temperature of the primary coolant supply, including where the coolant is water from the primary main supplied to the data center structure within a data center. In this non-limiting example, free-cooling by the outdoor chillers may be sufficient to lower the temperature of the liquid coolant for the air-cooling components, such that indoor or zone chillers otherwise used to lower the temperature of the coolant for air-cooling components may be deactivated.

Embodiments of the present disclosure are directed to a multistage cooling process for liquid coolant supplied to air-cooling components. In embodiments, liquid coolant is supplied by the outdoor chillers at a first temperature to coolant distribution units for liquid-cooled components. The liquid coolant at a first temperature is also received by the indoor or zone chillers, which adjusts the temperature of the liquid coolant to a second temperature for the air-cooling components. In some instances, the second temperature for the liquid coolant is less than the first temperature, as the range of operating temperatures for the air-cooling components is less than the range of operating temperatures for the coolant distribution units (and/or the liquid-cooled components).

In one non-limiting example, the one or more outdoor chillers are thermally coupled to one or more liquid-cooled components. A primary liquid coolant having a range of operating temperatures such as, but not limited to, between 80 degrees Fahrenheit (° F.) and 110° F. may be circulated between the one or more outdoor chillers and one or more CDUs. By way of another example, a secondary liquid coolant having a range of operating temperatures such as, but not limited to, between 85° F. and 95° F. may be circulated between the one or more CDUs and the one or more liquid-cooled components. The coolant distribution units provide benefits such as managing, pumping, and more precisely controlling coolant flow, temperature, and pressure through the liquid-cooled components. However, it is noted that the primary liquid coolant may instead be circulated between the outdoor chillers and the one or more liquid-cooled components directly and without need for the intervening coolant distribution units, including where the temperature of the primary liquid coolant and the operating temperature for the liquid-cooled components overlap, without departing from the scope of the present disclosure.

In another non-limiting example, the one or more outdoor chillers are thermally coupled to one or more air-cooling components. The primary liquid coolant having a range of operating temperatures such as, but not limited to, between 80° F. and 110° F. may be circulated between the one or more outdoor chillers and one or more indoor or zone chillers. The one or more indoor or zone chillers may reduce the temperature of the primary liquid coolant to a range of operating temperatures such as, but not limited to, between 55° F. and 65° F., before circulating the primary liquid coolant through the one or more air-cooling components. At this range of temperatures, the one or more air-cooling components may produce air conditioning that circulates around air-cooled components.

Embodiments of the present disclosure are directed to determining an efficiency of outdoor chiller power consumption when cooling the liquid coolant to be supplied to liquid-cooled components, either alone or in combination to the liquid coolant being supplied to air-cooling components. Embodiments of the present disclosure are also directed to a flexibility adjusting the temperature of supply side liquid coolant when utilizing the outdoor chillers versus zone chillers to cool the air as the percentage of air-cooling components versus liquid-cooled components changes. It is noted that this flexibility may be desirable with the installation or removal of liquid-cooled or air-cooling components, which adjusts the percentage of air-cooling components versus liquid-cooled components being supplied by the one or more outdoor chillers. In addition, it is noted that this flexibility may be desirable with the temporary activation or deactivation of liquid-cooled or air-cooling components, which also adjusts the percentage of air-cooling components versus liquid-cooled components being supplied by the one or more outdoor chillers.

In one non-limiting example, the percentage of air-cooling components versus liquid-cooled components is such that efficiency is increased by using the outdoor chillers to cool the primary liquid coolant to the range of operating temperatures for the liquid-cooled components, and additionally using the indoor or zone chillers for multistage temperature adjustment of the primary liquid coolant supplied to the air-cooling components to a second range of operating temperatures. In another non-limiting example, the percentage of air-cooling components versus liquid-cooled components is such that efficiency is increased by using the outdoor chillers to cool the primary liquid coolant to the range of operating temperatures for the air-cooling components, and additionally circulating the primary liquid coolant at that range of operating temperature to the liquid-cooled components.

Although the above discusses ranges of operating temperatures, it should be understood that the systems of methods of the present disclosure are configurable to maintain static temperatures for each of the primary liquid coolant, the secondary liquid coolant, and the indoor or zone coolant which typically cools air-cooled loads, without departing from the scope of the present disclosure. However, it is contemplated that variances in the operational parameters within the data center may observe temperature fluctuations or ranges, including in the circulated air and/or on the return side for the secondary liquid coolant and/or the primary liquid coolant. As such, the present disclosure is intended to cover both specific maintained operating temperatures within more general ranges of operating temperatures.

A first aspect of the present disclosure is to provide a system as substantially described herein.

A second aspect of the present disclosure is to provide a method as substantially described herein.

A third aspect of the present disclosure is to provide a non-transitory computer-readable medium having stored thereon instructions that, when read by at least one microprocessor, cause the at least one microprocessor to perform the operations as substantially described herein.

A fourth aspect of the present disclosure is to provide a system, comprising means for performing the operations as substantially described herein.

A fifth aspect of the present disclosure is to provide a cooling system and/or method comprising one or more air cooled outdoor chillers with integrated or separate free-cooling heat exchangers operating at a relatively high water supply temperature (e.g., 75° F. to 95° F., including 75° to 85° F.), on warmer days. The cooling system and/or method comprises one or more water-cooled indoor chillers operating at a relatively lower water supply temperature, (e.g., 55° F. to 65° F.). The cooling system and/or method comprises, where water is supplied from the outdoor chillers to the indoor or zone chillers, the water being divided into two streams within or upstream of the indoor or zone chillers including an evaporating water stream in a series water flow arrangement through evaporator(s), through air-cooled load(s) including but not limited to, fan-coil units, and through condenser(s) and a separate variable flow condenser water stream in parallel with the first series water stream. The cooling system and/or method comprises the aforementioned series water stream being used to cool air-cooled load(s) such as fan-coil units and then flow through a condenser to condense refrigerant from the indoor or zone chiller(s) compressor(s). The cooling system and/or method comprises the series evaporator/condenser water stream being cooled by the indoor or zone chiller(s) evaporator(s) from the relatively high water supply temperature of the outdoor chillers to the relatively low supply temperature of the indoor or zone chiller(s).

The cooling system and/or method of the fifth aspect may include, optionally, a second automatically acting throttleable parallel water stream from the outdoor chiller(s) that may blend with water entering the indoor or zone chiller(s) condenser(s) at times when the water temperature is above a certain adjustable threshold value (e.g., at least 110° F.). When the water temperature is not above the certain adjustable threshold value, a valve for the second parallel water stream is automatically closed, reducing water flow and pumping power within the system.

The cooling system and/or method of the fifth aspect may include one or more of the previous embodiments and, optionally, the relatively high water supply temperature from the outdoor chillers being used to cool corresponding cooling loads that can be adequately cooled by the higher water supply temperature. For example, liquid-cooled data center cooling equipment typically requires an 80° F. to 90° F. water supply temperature. The relatively high water supply temperature from the outdoor chiller(s) may be used to cool liquid-cooled data center equipment directly, or may be used as a primary coolant in a cooling distributing unit where a secondary coolant is cooled and supplied to the liquid-cooled equipment by separate additional pump(s).

The cooling system and/or method of the fifth aspect may include one or more of the previous embodiments and, optionally, the coolant from the indoor chillers being supplied to equipment that requires a relatively lower water supply temperature. For example, air-cooling fan coil units typically require supply water at a lower temperature, e.g., 55° F. to 65° F.

The cooling system and/or method of the fifth aspect may include one or more of the previous embodiments and, optionally, wherein the water supply temperature setpoint of the outdoor chillers may be manually or automatically (or substantially automatically) continuously varied from an upper to a lower limit based on parameters, such as outdoor air temperature and proportion of higher versus lower temperature cooling loads.

The cooling system and/or method of the fifth aspect may include one or more of the previous embodiments and, optionally, wherein the upper limit is the highest water supply temperature that can adequately cool the higher-temperature indoor loads, such as liquid-cooled data center equipment or cooling distribution units for liquid-cooled equipment.

The cooling system and/or method of the fifth aspect may include one or more of the previous embodiments and, optionally, wherein the lower temperature limit is the lowest temperature that can adequately cool the lower temperature indoor loads without risk of condensation occurring on indoor fan coil heat exchangers.

The cooling system and/or method of the fifth aspect may include one or more of the previous embodiments and, optionally, wherein the entire cooling system is capable of operating in a free-cooling mode. For example, when outdoor ambient temperature is sufficiently low, the coolant cooler(s) associated with the outdoor chiller(s) may produce water at 55° F. to 65° F. without additional compressor cooling. Since this lower water supply temperature can adequately cool both the higher temperature and lower temperature cooling loads, the indoor compressors may also be stopped. Thus, the entire system operates in a free cooling mode with no compressors running.

A sixth aspect of the present disclosure is to provide a zone chiller for a multistage high-efficiency cooling system. The zone chiller includes an evaporator that receives primary coolant from a primary coolant supply via a first inlet at a first temperature and provides zone coolant via a first outlet at a second temperature to a zone coolant supply. The zone chiller includes a condenser that receives primary coolant from the primary coolant supply in a first inlet at the first temperature, where the primary coolant is provided in series with and controllably mixable with zone coolant received from a zone coolant return at a third temperature prior to the first inlet of the condenser, and where the primary coolant is provided via a first outlet of the condenser to a primary coolant return. The zone chiller includes a compressor able to circulate refrigerant from a second outlet of the evaporator to a second inlet of the condenser, and from a second outlet of the condenser to a second inlet of the evaporator, to form a refrigerant loop between the evaporator, the compressor, and the condenser.

The zone chiller of the sixth aspect may include, optionally, when the compressor is activated to circulate the refrigerant, heat is transferred from the primary coolant received by the first inlet of the evaporator to the primary coolant received by the first inlet of the condenser, the second temperature is less than the first temperature, and the third temperature is greater than the second temperature.

The zone chiller of the sixth aspect may include one or more of the previous embodiments and, optionally, when the compressor is not activated to circulate the refrigerant, heat is not transferred from the primary coolant received by the first inlet of the evaporator to the primary coolant received by the first inlet of the condenser, the second temperature is substantially equivalent to the first temperature, and the third temperature is greater than the second temperature.

The zone chiller of the sixth aspect may include one or more of the previous embodiments and, optionally, further comprising a flow control valve for the primary coolant prior to the first inlet of the condenser, where the flow control valve controls a flow of primary coolant from the primary coolant supply to the first inlet of the condenser prior to the mixing of the zone coolant with the primary coolant.

The zone chiller of the sixth aspect may include one or more of the previous embodiments and, optionally, further comprising one or more temperature transducers to monitor at least one of coolant temperature and refrigerant temperature within the zone chiller.

The zone chiller of the sixth aspect may include one or more of the previous embodiments and, optionally, further comprising one or more pressure transducers to monitor at least one of coolant pressure and refrigerant pressure within the zone chiller.

The zone chiller of the sixth aspect may include one or more of the previous embodiments and, optionally, further comprising a receiver able to receive the refrigerant circulated in a liquid state from the second outlet of the condenser, and an expansion valve able to receive the refrigerant circulated in the liquid state from the receiver and able to provide the refrigerant circulated in the liquid state to the second inlet of the evaporator.

The zone chiller of the sixth aspect may include one or more of the previous embodiments and, optionally, further comprising a load-balancing valve in fluidic communication with the compressor and the second inlet of the evaporator, where the load-balancing valve provides refrigerant from the compressor to the second inlet of the evaporator instead of the refrigerant provided from the second outlet of the condenser to the second inlet of the evaporator.

The zone chiller of the sixth aspect may include one or more of the previous embodiments and, optionally, where at least a portion of the refrigerant is provided from the second outlet of the condenser to the compressor for compressor cooling.

A seventh aspect of the present disclosure is to provide a multistage high-efficiency cooling system. The cooling system includes an outdoor chiller in fluidic communication with a primary coolant supply and a primary coolant return, where the outdoor chiller provides primary coolant at a first temperature via the primary coolant supply. The cooling system includes a zone chiller in fluidic communication with the primary coolant supply and the primary coolant return. The zone chiller includes an evaporator that receives primary coolant from the primary coolant supply via a first inlet at a first temperature and provides zone coolant via a first outlet at a second temperature to a zone coolant supply. The zone chiller includes a condenser that receives primary coolant from the primary coolant supply in a first inlet at the first temperature, where the primary coolant is provided in series with and controllably mixable with zone coolant received from a zone coolant return at a third temperature prior to the first inlet of the condenser, and where the primary coolant is provided via a first outlet of the condenser to a primary coolant return. The zone chiller includes a compressor able to circulate refrigerant from a second outlet of the evaporator to a second inlet of the condenser, and from a second outlet of the condenser to a second inlet of the evaporator, to form a refrigerant loop between the evaporator, the compressor, and the condenser.

The multistage high-efficiency cooling system of the seventh aspect may include, optionally, an air-cooling component in fluidic communication with the zone coolant supply and the zone coolant return, where the air-cooling component is located proximate to an air-cooled component, and where circulated air transfers heat to the zone coolant to change the zone coolant from the second temperature to the third temperature.

The multistage high-efficiency cooling system of the seventh aspect may include one or more of the previous embodiments and, optionally, where the air-cooled component is a server, a server rack, or a server cabinet.

The multistage high-efficiency cooling system of the seventh aspect may include one or more of the previous embodiments and, optionally, when the compressor is activated to circulate the refrigerant, heat is transferred from the primary coolant received by the first inlet of the evaporator to the primary coolant received by the first inlet of the condenser, the second temperature is less than the first temperature, and the third temperature is greater than the second temperature.

The multistage high-efficiency cooling system of the seventh aspect may include one or more of the previous embodiments and, optionally, when the compressor is not activated to circulate the refrigerant, heat is not transferred from the primary coolant received by the first inlet of the evaporator to the primary coolant received by the first inlet of the condenser, the second temperature is substantially equivalent to the first temperature, and the third temperature is greater than the second temperature.

The multistage high-efficiency cooling system of the seventh aspect may include one or more of the previous embodiments and, optionally, further comprising a coolant distribution unit in fluidic communication with a secondary coolant supply and a secondary coolant return and in fluidic communication with the primary coolant supply and the primary coolant return, and a liquid-cooled component in fluidic communication with the secondary coolant supply and the secondary coolant return.

The multistage high-efficiency cooling system of the seventh aspect may include one or more of the previous embodiments and, optionally, where the coolant distribution unit receives primary coolant from the primary coolant supply at the first temperature and provides the primary coolant to the primary coolant return at a fourth temperature.

The multistage high-efficiency cooling system of the seventh aspect may include one or more of the previous embodiments and, optionally, where the liquid-cooled component is a server, a server rack, or a server cabinet.

An eighth aspect of the present disclosure is to provide a method of operating a zone chiller for a multistage high-efficiency cooling system. The method may include, but is not limited to, receiving primary coolant at a first temperature from a primary coolant supply with a first inlet of an evaporator. The method may include, but is not limited to, receiving primary coolant at the first temperature from the primary coolant supply with a first inlet of a condenser. The method may include, but is not limited to, providing zone coolant at a second temperature via a first outlet of the evaporator to a zone coolant supply. The method may include, but is not limited to, receiving zone coolant via the first inlet of the condenser at a third temperature, where the primary coolant is provided in series with and controllably mixable with the zone coolant received from a zone coolant return at the third temperature prior to the first inlet of the condenser. The method may include, but is not limited to, providing primary coolant controllably mixed with returned zone coolant via a first outlet of the condenser to a primary coolant return. The evaporator and the condenser are within a refrigerant loop with a compressor able to circulate refrigerant from a second outlet of the evaporator to a second inlet of the condenser, and from a second outlet of the condenser to a second inlet of the evaporator.

The method of the eighth aspect may include, optionally, when the compressor is activated to circulate the refrigerant, heat is transferred from the primary coolant received by the first inlet of the evaporator to the primary coolant received by the first inlet of the condenser, the second temperature is less than the first temperature, and the third temperature is greater than the second temperature.

The method of the eighth aspect may include one or more of the previous embodiments and, optionally, when the compressor is not activated to circulate the refrigerant, heat is not transferred from the primary coolant received by the first inlet of the evaporator to the primary coolant received by the first inlet of the condenser, the second temperature is substantially equivalent to the first temperature, and the third temperature is greater than the second temperature.

The phrases “at least one,” “one or more,” and “and/or,” as used herein, are open-ended expressions that are both conjunctive and disjunctive in operation. For example, each of the expressions “at least one of A, B and C,” “at least one of A, B, or C,” “one or more of A, B, and C,” “one or more of A, B, or C,” and “A, B, and/or C” means A alone, B alone, C alone, A and B together, A and C together, B and C together, or A, B and C together.

Unless otherwise indicated, all numbers expressing quantities, dimensions, conditions, and so forth used in the specification and claims are to be understood as being modified in all instances by the term “about” or “approximately.” As used herein, unless otherwise specified, the terms “about,” “approximately,” etc., when used in relation to numerical limitations or ranges, mean that the recited limitation or range may vary by up to 10%. By way of non-limiting example, “about 750” can mean as little as 675 or as much as 825, or any value therebetween. When used in relation to ratios or relationships between two or more numerical limitations or ranges, the terms “about,” “approximately,” etc. mean that each of the limitations or ranges may vary by up to 10%; by way of non-limiting example, a statement that two quantities are “approximately equal” can mean that a ratio between the two quantities is as little as 0.9:1.1 or as much as 1.1:0.9 (or any value therebetween), and a statement that a four-way ratio is “about 5:3:1:1” can mean that the first number in the ratio can be any value of at least 4.5 and no more than 5.5, the second number in the ratio can be any value of at least 2.7 and no more than 3.3, and so on.

The use of “substantially” in the present disclosure, when referring to a measurable quantity (e.g., a diameter or other distance) and used for purposes of comparison, is intended to mean within 5% of the comparative quantity. The terms “substantially similar to,” “substantially the same as,” and “substantially equal to,” as used herein, should be interpreted as if explicitly reciting and encompassing the special case in which the items of comparison are “similar to,” “the same as” and “equal to,” respectively.

The term “a” or “an” entity, as used herein, refers to one or more of that entity. As such, the terms “a” (or “an”), “one or more” and “at least one” can be used interchangeably herein.

The use of “including,” “comprising,” or “having” and variations thereof herein is meant to encompass the items listed thereafter and equivalents thereof as well as additional items. Accordingly, the terms “including,” “comprising,” or “having” and variations thereof can be used interchangeably herein. The use of “engaged with” and variations thereof herein is meant to encompass any direct or indirect connections between components.

It shall be understood that the term “means” as used herein shall be given its broadest possible interpretation in accordance with 35 U.S.C. § 112(f). Accordingly, a claim incorporating the term “means” shall cover all structures, materials, or acts set forth herein, and all of the equivalents thereof. Further, the structures, materials, or acts and the equivalents thereof shall include all those described in the Summary, Brief Description of the Drawings, Detailed Description, Abstract, and claims themselves.

These and other advantages will be apparent from the disclosure of the invention(s) contained herein. The above-described embodiments, objectives, and configurations are neither complete nor exhaustive. The Summary is neither intended nor should it be construed as being representative of the full extent and scope of the present disclosure. Moreover, references made herein to “the present disclosure” or aspects thereof should be understood to mean certain embodiments of the present disclosure and should not necessarily be construed as limiting all embodiments to a particular description. The present disclosure is set forth in various levels of detail in the Summary as well as in the attached drawings and the Detailed Description and no limitation as to the scope of the present disclosure is intended by either the inclusion or non-inclusion of elements, components, etc. in this Summary. Additional aspects of the present disclosure will become more readily apparent from the Detailed Description, particularly when taken together with the drawings.

It is to be appreciated that any feature or aspect described herein can be claimed in combination with any other feature(s) or aspect(s) as described herein, regardless of whether the features or aspects come from the same described embodiment.

Any one or more aspects described herein can be combined with any other one or more aspects described herein. Any one or more features described herein can be combined with any other one or more features described herein. Any one or more embodiments described herein can be combined with any other one or more embodiments described herein.

### BRIEF DESCRIPTION OF THE DRAWINGS

Those of skill in the art will recognize that the following description is merely illustrative of the principles of the disclosure, which may be applied in various ways to provide many different alternative embodiments. This description is made for illustrating the general principles of the teachings of this disclosure and is not meant to limit the inventive concepts disclosed herein.

The accompanying drawings illustrate embodiments of the disclosure and together with the general description of the disclosure given above and the detailed description of the drawings given below, serve to explain the principles of the disclosure.

FIG. 1 is a schematic of a multistage high-efficiency cooling system with indoor or zone chillers, in accordance with one or more embodiments of the present disclosure;

FIG. 2 is a schematic of a portion of the multistage high-efficiency cooling system of FIG. 1, including a previously-known configuration for the indoor or zone chiller;

FIG. 3 is a schematic of a portion of the multistage high-efficiency cooling system of FIG. 1, including an improved configuration for the indoor or zone chiller, in accordance with one or more embodiments of the present disclosure;

FIG. 4 is a schematic of a control system including the multistage high-efficiency cooling system of FIG. 1, in accordance with one or more embodiments of the present disclosure;

FIG. 5 is a flow diagram of a method or process for operating a multistage high-efficiency cooling system of FIG. 1, in accordance with one or more embodiments of the present disclosure; and

FIG. 6 is a flow diagram of a method or process for operating a multistage high-efficiency cooling system of FIG. 1, in accordance with one or more embodiments of the present disclosure.

It should be understood that the drawings are not necessarily to scale, and various dimensions may be altered. In certain instances, details that are not necessary for an understanding of the disclosure or that render other details difficult to perceive may have been omitted. It should be understood, of course, that the disclosure is not necessarily limited to the particular embodiments illustrated herein. It is noted that any line in the drawings may be illustrated as solid or broken lines, including any section or length of each individual line, without departing from the scope of the present disclosure.

It will be appreciated that recitation of, for example, reference character 117, 117A, 117B, etc. may apply to any combination of reference characters 117, 117A, 117B, etc. In addition, it will be appreciated any reference characters “xx01”, “01”, and “1”, etc. within the figures and the description are referring to the same component within a system or operation of a method.

In the figures:
100 System
102 Outdoor Chiller
104, 104A, 104B Primary Coolant Supply
106, 106A, 106B Primary Coolant Return
108 Coolant Distribution Unit
110 Secondary Coolant Supply
112 Secondary Coolant Return
114 Liquid-Cooled Component
116 Thermal Storage Module
118, 118A, 118B Indoor or Zone Chiller
120A, 120B Indoor or Zone Coolant Supply
122A, 122B Indoor or Zone Coolant Return
124 Air-Cooling Component
200 Evaporator
202 Condenser
204 Compressor
206 Indoor or Zone Chiller Inlet from Outdoor Chiller Coolant Supply
208 Evaporator Coolant Inlet
210 Condenser Coolant Inlet
212 Strainer
214 Transducer
216 Valve
218 Evaporator Coolant Outlet
220 Indoor or Zone Chiller Coolant Outlet to Air-Cooling Components
222 Indoor or Zone Chiller Inlet from Air-Cooling Components
224 Condenser Outlet
226 Indoor or Zone Chiller Outlet to Outdoor Chiller Coolant Return
228 Valve
230 Evaporator Refrigerant Outlet
232 Compressor Refrigerant Inlet
234 Transducer
236 Valve
238 Compressor Refrigerant Outlet
240 Check Valve
242 Condenser Refrigerant Inlet
244 Evaporator Refrigerant Inlet
246 Transducer
248 Control Valve
250 Condenser Refrigerant Outlet
252 Receiver
254 Expansion Valve
256 Compressor Cooling Inlet
258 Sight Glass
260 Valve
300 Evaporator
302 Condenser
304 Compressor
306 Indoor or Zone Chiller Inlet from Outdoor Chiller Coolant Supply
308 Evaporator Coolant Inlet
310 Condenser Coolant Inlet
311 Flow Control Valve
312 Strainer
314 Transducer
316 Valve
318 Evaporator Coolant Outlet
320 Indoor or Zone Chiller Coolant Outlet to Air-Cooling Components
321 Transducer
322 Indoor or Zone Chiller Inlet from Air-Cooling Components
324 Condenser Coolant Outlet
326 Indoor or Zone Chiller Coolant Outlet to Outdoor Chiller Return
327 Expansion Joint
328 Transducer
329 Valve
330 Evaporator Refrigerant Outlet
332 Compressor Refrigerant Inlet
334 Transducer
336 Valve
338 Compressor Refrigerant Outlet
340 Check Valve
342 Condenser Refrigerant Inlet
344 Evaporator Refrigerant Inlet
346 Transducer
348 Valve
350 Condenser Refrigerant Outlet
352 Receiver
354 Expansion Valve
356 Compressor Cooling Inlet
358 Sight Glass
360 Valve
361 Filter
362 Load-Balancing Valve
400 Control System
401 Data
402 Control Unit
403 Air-Cooled Components
404 Processor
406 Memory
408 Instructions
410 User Interface
412 Display
414 User Input Device
416 Port Connectors
500 Method or Process
502 Provide Primary Coolant at First Temperature
504 Circulate Secondary Coolant
506 Receive Primary Coolant at Second Temperature
508 Adjust Temperature of Primary Coolant
510 Provide Zone Coolant at Third Temperature
512 Circulate Zone Coolant
514 Mix Zone Coolant at Fourth Temperature with Primary Coolant
516 Receive Mixture of Zone Coolant and Primary Coolant
600 Method or Process
602 Observe Operation Parameters of System
604 Perform Operations of Method or Process 500
606 Provide Primary Coolant at Third Temperature
608 Circulate Zone Coolant
610 Mix Zone Coolant at Fourth Temperature with Primary Coolant
612 Receive Mixture of Zone Coolant and Primary Coolant

### DETAILED DESCRIPTION

Although the following text sets forth a detailed description of numerous different embodiments, it should be understood that the legal scope of the description is defined by the words of the claims set forth at the end of this disclosure. The Detailed Description is to be construed as exemplary only and does not describe every possible embodiment of the multistage high-efficiency cooling system since describing every possible embodiment would be impractical, if not impossible. Numerous alternative embodiments could be implemented, using either current technology or technology developed after the filing date of this patent, which would still fall within the scope of the claims. Additionally, any combination of features shown in the various figures can be used to create additional embodiments of the present disclosure. Thus, dimensions, aspects, and features of one embodiment of the multistage high-efficiency cooling system can be combined with dimensions, aspects, and features of another embodiment of the multistage high-efficiency cooling system to create the claimed embodiment.

Embodiments of the present disclosure are directed to multistage high-efficiency cooling system. The multistage high-efficiency cooling system includes outdoor chillers that are thermally coupled to liquid-cooled components, including optionally through intervening coolant distribution units. The outdoor chillers are thermally coupled to air-cooling components through indoor or zone chillers, where the air-cooling components provided air conditioning for air-cooled components.

Embodiments of the present disclosure are also directed to a control system for monitoring and adjusting the operation of the multistage high-efficiency cooling system. In some configurations, primary coolant is supplied by the outdoor chillers to the coolant distribution units (or the liquid-cooled components, directly) and additionally to the indoor or zone chillers at a first temperature. The indoor or zone chillers adjust the temperature of the primary coolant to a second temperature prior to the primary coolant reaching the air-cooling components. In other configurations, primary coolant is supplied by the outdoor chillers to the coolant distribution units (or the liquid-cooled components, directly) and additionally to the indoor or zone chillers at a temperature required by the air-cooling components, but which can also be utilized by the coolant distribution units (or the liquid-cooled components, directly).

Embodiments of the present disclosure are also directed to a method of operating the multistage high-efficiency cooling system. Embodiments of the present disclosure are also directed to a method of monitoring and adjusting the operation of the multistage high-efficiency cooling system. In one non-limiting example, embodiments of the present disclosure are directed to the optimizing of power consumption based on the ambient environment temperature and the percentage of liquid-cooling versus percentage of air-cooling utilized within a data center, which may take into consideration the temperature of the primary coolant supply including where the coolant is water from the primary main supplied to a structure housing the data center, including optionally to utilize free-cooling by the outdoor chillers in place of the indoor or zone chillers to reduce the operating temperature of the liquid coolant for the air-cooling components.

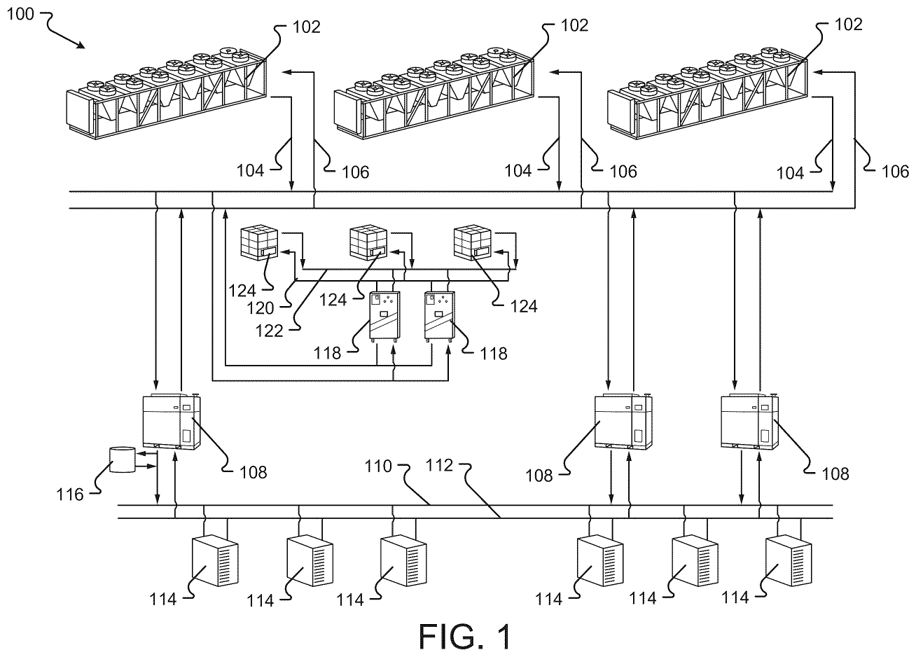

FIG. 1 illustrates a multistage high-efficiency cooling system 100 (or system 100), in accordance with one or more embodiments of the present disclosure.

In embodiments, the system 100 includes one or more outdoor chillers 102 (e.g., rooftop chillers, or the like) that are fluidically coupled to a primary coolant supply 104 and a primary coolant return 106. A primary coolant (e.g., water, a glycol, a water-glycol mixture, or another liquid capable of cooling) circulates through the one or more outdoor chillers 102, exiting the one or more outdoor chillers 102 via the primary coolant supply 104 at a first temperature and entering the one or more outdoor chillers 102 via the primary coolant return 106 at a second temperature. For example, the second temperature may be higher than the first temperature, as heat is transferred to the primary coolant prior to returning via the primary coolant return 106.

In some configurations, the primary coolant supply 104 and the primary coolant return 106 formed a closed loop, including optionally a tank or reservoir (e.g., for liquid coolant). However, it is contemplated that the loop for the primary coolant supply 104 and the primary coolant return 106 may be supplemented with a source including, but not limited to, a primary water main in communication with a data center structure housing the system 100, and the like.

In embodiments, the one or more outdoor chillers 102 operate to cool the primary coolant when the outdoor ambient temperature is above a threshold value (e.g., between approximately 75° F. and 80° F.). When the ambient temperature is below the threshold value, the one or more outdoor chillers 102 operate in free-cooling mode (or partial free-cooling mode) wherein the primary coolant is chilled by outdoor air, either alone or with assistance from a compressor.

In embodiments, the system 100 includes one or coolant distribution units 108 (or CDUs) that are fluidically coupled to the primary coolant supply 104 and the primary coolant return 106. For example, the primary coolant may circulate through the one or more coolant distribution units 108, entering the one or more coolant distribution units 108 via the primary coolant supply 104 at the first temperature and exiting the one or more coolant distribution units 108 via the primary coolant return 106 at the second temperature. In this regard, the one or more outdoor chillers 102 are thermally coupled to the one or more coolant distribution units 108.

In embodiments, the one or more coolant distribution units 108 are fluidically coupled to a secondary coolant supply 110 and a secondary coolant return 112. A secondary coolant (e.g., water, a glycol, a water-glycol mixture, or another liquid capable of cooling) circulates through the one or more coolant distribution units 108, exiting the one or more coolant distribution units 108 via the secondary coolant supply 110 at a first temperature and entering the one or more coolant distribution units 108 via the secondary coolant return 112 at a second temperature. For example, the second temperature may be higher than the first temperature, as heat is transferred to the secondary coolant prior to returning via the secondary coolant return 112.

In embodiments, the system 100 includes one or more liquid-cooled components 114 (e.g., servers, server racks, server cabinets, etc.) that are fluidically coupled to the secondary coolant supply 110 and the secondary coolant return 112. For example, the secondary coolant may circulate through the one or more liquid-cooled components 114, entering the one or more liquid-cooled components 114 via the secondary coolant supply 110 at the first temperature and exiting the one or more liquid-cooled components 114 via the secondary coolant return 112 at the second temperature. In this regard, the one or more outdoor chillers 102 are thermally coupled to the one or more liquid-cooled components 114, via the intervening one or more coolant distribution units 108, such that the one or more outdoor chillers 102 assist in maintaining the operational temperature of the one or more liquid-cooled components 114.

In embodiments, at least one thermal storage module 116 is fluidically coupled to the primary coolant supply 104 and/or the secondary coolant supply 110. For example, the thermal storage module 116 may be a passive module (e.g., a tank, reservoir, or other fluid-storing element) able to store the secondary coolant received from the coolant distribution unit 108 at a particular temperature. By way of another example, the thermal storage module 116 may be an active module (e.g., as a tank or other fluid-storing element) able to store the secondary coolant received from the coolant distribution unit 108 at a particular temperature, and/or able to adjust the temperature of the secondary coolant (e.g., including thermally recharging the secondary coolant) to supplement the operation of the coolant distribution unit 108. In some configurations, the thermal storage module 116 is provided with a pump, heat exchangers, and/or compressors. However, it should be understood that the at least one thermal storage module 116 may be optional within the system 100, without departing from the scope of the present disclosure.

Although embodiments of the present disclosure include the thermal coupling of the one or more outdoor chillers 102 and the one or more liquid-cooled components 114 via a primary coolant and secondary coolant that passes through the intervening one or more coolant distribution units 108, it should be understood that the primary coolant may be circulated directly through the one or more liquid-cooled components 114 via the primary coolant supply 104 and the primary coolant return 106 without departing from the scope of the present disclosure. For example, this may be beneficial where there are few (or no) air-cooling components, such that the temperature of the coolant that exits the one or more outdoor chillers 102 via the primary coolant supply 104 is provided mostly (or only) to the one or more liquid-cooled components 114. As such, the one or more coolant distribution units 108, the secondary coolant supply 110, and the secondary coolant return 112 may be considered optional for purposes of the present disclosure.

In embodiments, the system 100 includes one or more zone chillers 118 that are fluidically coupled to the primary coolant supply 104 and the primary coolant return 106. In some non-limiting configurations for the system 100, the zone chillers 118 may be located within a data center structure, such that the one or more zone chillers 118 may be considered indoor chillers, for purposes of the present disclosure.

The primary coolant circulates through the one or more zone chillers 118, entering the one or more zone chillers 118 via the primary coolant supply 104 at the first temperature and exiting the one or more zone chillers 118 via the primary coolant return 106 at a different temperature. In one non-limiting example, the different temperature may be similar to the second temperature for the primary coolant, as circulated from the one or more coolant distribution units 108 (or the one or more liquid-cooled components 114) to not have a disparity between the primary coolant returned to the one or more outdoor chillers 102, although it is contemplated that the temperature of the primary coolant returned from the one or more zone chillers 118 may be any temperature. In this regard, the one or more outdoor chillers 102 are thermally coupled to the one or more zone chillers 118.

In embodiments, the one or zone chillers 118 are fluidically coupled to a zone coolant supply 120 and a zone coolant return 122. Zone coolant (e.g., water, a glycol, a water-glycol mixture, or another liquid capable of cooling) circulates through the one or zone chillers 118, exiting the one or zone chillers 118 via the zone coolant supply 120 at a first temperature and entering the one or zone chillers 118 via the zone coolant return 122 at a second temperature. For example, the second temperature may be higher than the first temperature, as heat is transferred to the zone coolant prior to returning via the zone coolant return 122.

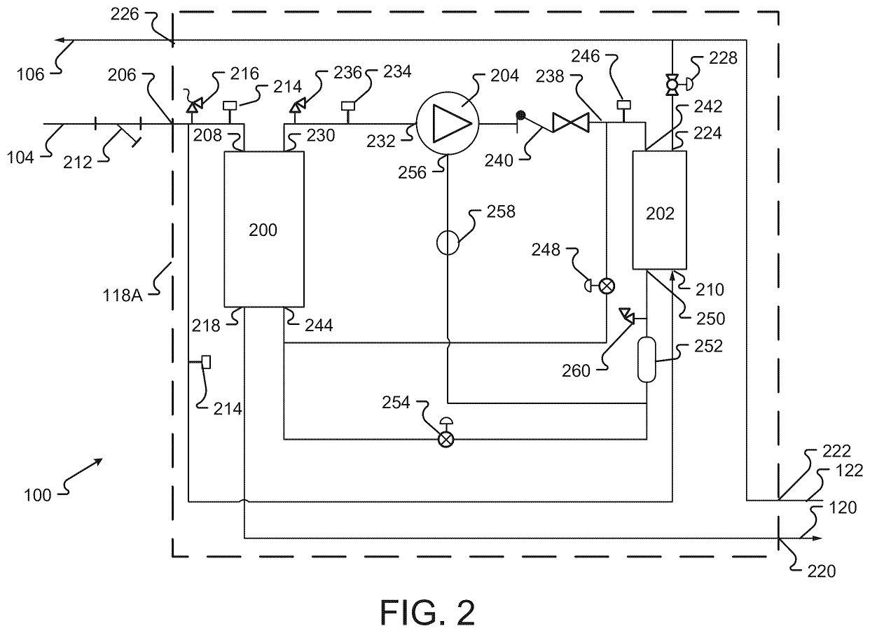

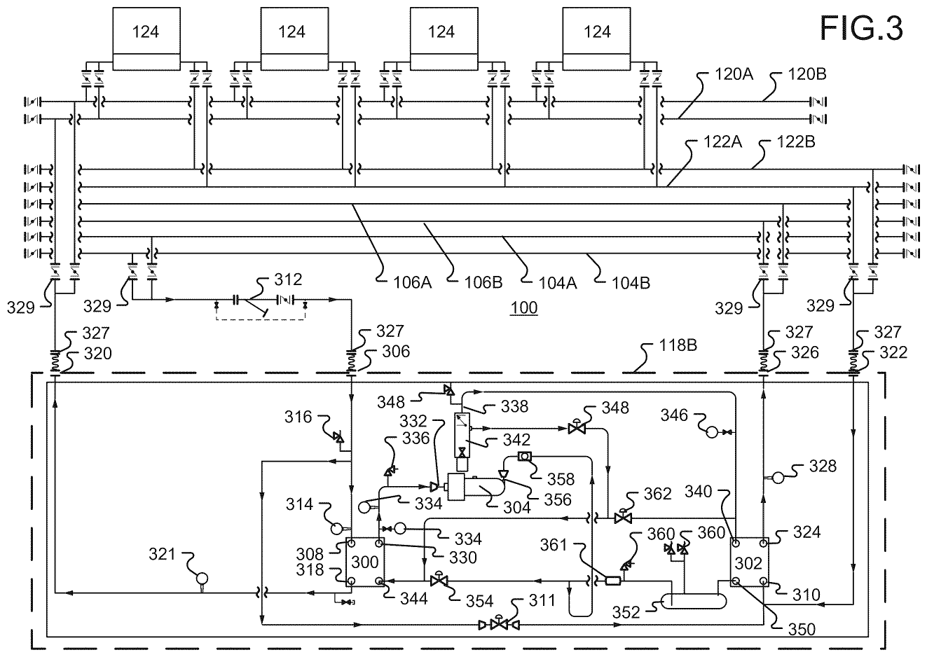

In embodiments, the system 100 includes one or more air-cooling components 124 (e.g., a computer room air conditioner (or CRAC), a close control unit, a critical cooling unit, or other air conditioning unit), where the one or more air-cooling components 124 are fluidically coupled to the zone coolant supply 120 and the zone coolant return 122. The air-cooling components 124 are located in proximity to air-cooled components (e.g., servers, server racks, server cabinets, etc.). For example, the secondary coolant may circulate through the one or more air-cooling components 124, entering the one or more air-cooling components 124 via the zone coolant supply 120 at the first temperature and exiting the one or more air-cooling components 124 via the zone coolant return 122 at the second temperature. In this regard, the one or more outdoor chillers 102 are thermally coupled to the one or more air-cooling components 124 (and thus the proximate air-cooled components) via the one or more zone chillers 118, such that the one or more outdoor chillers 102 assist in maintaining the operational temperature of the one or more air-cooling components 124. It is noted that further discussion regarding the circulation of the liquid coolant through the one or more zone chillers 118 and the one or more air-cooling components 124 is provided with respect to FIGS. 2 and 3, where FIG. 2 illustrates one known configuration for the one or more zone chillers 118 and FIG. 3 illustrates improvements over the known configurations of FIG. 2.

It is contemplated that the lower temperature limit of the range of operating temperatures for the zone coolant supplied to the air-cooling components 124 is the lowest temperature that can adequately cool the lower temperature indoor loads without risk of condensation occurring on indoor fan coil heat exchangers. In some configurations, relative humidity within the air-cooling components 124, the zone chiller 118, and/or the system 100 in general may be sensed with one or more sensors and programmed to trigger appropriate responses to condensation (e.g., in communication with control system 400, described in detail further herein).

It is noted that the system 100 may be adaptable to any heat transfer medium for the primary coolant supplied by the primary coolant supply 104, the secondary coolant supplied by the secondary coolant supply 110, and/or the zone coolant supplied by the zone coolant supply 120. The system 100 is designed to operate with either water and/or glycol-based solutions as required, enabling enhanced adaptability to various cooling needs and environmental conditions. The use of glycol is particularly advantageous where freeze protection is necessary or where site conditions warrant its use for advanced corrosion protection. Additionally or alternatively, the system may operate using water (e.g., facility main water) alone.

Although not shown, it should be understood that the system 100 may include multiple of the primary coolant supply 104, the primary coolant return 106, the secondary coolant supply 110, the secondary coolant return 112, the zone coolant supply 120, and/or the zone coolant return 122, without departing from the scope of the present disclosure. For example, the system 100 may have redundancies of the primary coolant supply 104, the primary coolant return 106, the secondary coolant supply 110, the secondary coolant return 112, the zone coolant supply 120, and/or the zone coolant return 122 to meet code requirements. For instance, the portion of the system 100 shown in FIG. 3 illustrates redundancies, labelled “A” and “B” for the primary coolant supply 104, the primary coolant return 106, the zone coolant supply 120, and the zone coolant return 122. Although not shown in FIG. 3, it should be understood that redundancies for the secondary coolant supply 110 and the second coolant return 112 may also be included in system 100.

Referring generally to FIGS. 2 and 3, two variations in the operation of the zone chillers 118 is provided. In particular, FIG. 2 shows a known configuration for a zone chiller 118A, with multiple sources of coolant return for the zone chiller 118A such as coolant return from the air-cooling components 124 being in parallel with coolant supply from a condenser 202 (and optionally mixing with) coolant return from the condenser 202. In contrast, FIG. 3 and embodiments of the present disclosure disclose improvements over the known configuration of FIG. 2, with coolant return from the air-cooling components 124 being in series with (and optionally mixed with) coolant input to a condenser 302 of a zone chiller 118B, such that only the condenser output is the source for coolant return from the zone chiller 118B.

Generally, in FIGS. 2 and 3, the primary coolant is supplied from the outdoor chillers 102 to the respective zone chillers 118A, 118B, and is divided into two streams within or upstream of the respective zone chillers 118A, 118B: 1) a condenser coolant stream and 2) an evaporator coolant stream. The condenser coolant stream is used to condense refrigerant within a compressor of the respective zone chillers 118A, 118B. The evaporator coolant stream is cooled by the evaporator of the respective zone chillers 118A, 118B from a relatively high supply temperature of the primary coolant from the outdoor chillers 102 to a relatively low supply temperature from the respective zone chillers 118A, 118B to the air-cooling components 124.

Referring now to FIG. 2, the known configuration of the zone chiller 118A includes an evaporator 200, a condenser 202, and a compressor 204 in fluidic communication therebetween. Primary coolant from the primary coolant supply 104 is provided to an inlet 206 of the zone chiller 118A. The inlet 206 of the zone chiller 118A is in fluid communication with an inlet 208 of the evaporator 200 and an inlet 210 of the condenser 202. Optionally, the primary coolant passes through one or more fluidic components prior to reaching the inlet 208 of the evaporator 200 and/or the inlet 210 of the condenser 202. For example, the one or more fluidic components may include, but are not limited to, at least one strainer 212, at least one transducer 214 (e.g., a temperature transducer, a pressure transducer, etc.), at least one valve 216, and/or a filter. For instance, the at least one valve 216 may include, but is not limited to, a relief valve.

An outlet 218 of the evaporator 200 is fluidically coupled to an outlet 220 of the zone chiller 118A, which in turn is fluidically coupled to the zone coolant supply 120 for the one or more air-cooling components 124 (not shown). Optionally, zone coolant from the evaporator 200 passes through one or more fluidic components prior to reaching the outlet 220 of the zone chiller 118A. For example, the one or more fluidic components may include, but are not limited to, at least one transducer (e.g., a temperature transducer, a pressure transducer, etc.), at least one valve, and/or a filter.

It is noted that the primary coolant from the primary coolant supply 104 that enters the inlet 208 of the evaporator 200 becomes the zone coolant that exits the outlet 218 of the evaporator 200 (and the outlet 220 of the zone chiller 118A) for the zone coolant supply 120. Although the temperature of the primary coolant is adjusted (e.g., lowered) by the operation of the evaporator 200, the same coolant flows through the evaporator 200 between the inlet 208 and the outlet 218.

The zone coolant return 122 is in fluid communication with an inlet 222 of the zone chiller 118A. The inlet 222 of the zone chiller 118A is in fluid communication with an outlet 224 of the condenser 202 and an outlet 226 of the zone chiller 118A, which in turn is fluidically coupled to the primary coolant return 106 for the system 100. Optionally, the primary coolant and/or the zone coolant passes through one or more fluidic components prior to reaching the outlet 226 of the zone chiller 118A. For example, the one or more fluidic components may include, but are not limited to, at least one transducer (e.g., a temperature transducer, a pressure transducer, etc.), at least one valve 228, and/or a filter. For instance, the at least one valve 228 may include, but is not limited to, a control valve.

It is noted that the zone coolant from the zone coolant return 122 becomes the primary coolant that exits the outlet 226 of the zone chiller 118A for the primary coolant return 106. The same coolant flows between the inlet 222 and the outlet 226 of the zone chiller 118A, although the temperature of the coolant may be adjusted (e.g., raised) by the mixing of primary coolant that passes through the condenser 202. In particular, the coolant supplied to the inlet 210 of the condenser 202 and the coolant supplied to the zone coolant supply 120 from the evaporator 200 are provided in parallel. In addition, the coolant received from the outlet 224 of the condenser 202 and the coolant received from the zone coolant return 122 are provided in parallel, prior to mixing together before exiting zone chiller 118A via the outlet 226.

A refrigerant circulates in a loop between the evaporator 200 and the condenser 202. The refrigerant transitions between gaseous and liquid form during circulation, transferring heat between (1) coolant from the primary coolant supply 104 passing from the inlet 208 to the outlet 218 through the evaporator 200 and (2) refrigerant from the primary coolant supply 104 passing through the condenser 202.

The refrigerant exits an outlet 230 of the evaporator 200 in gaseous form after heat is transferred from the coolant received from the primary coolant supply 104 to the refrigerant to cool the coolant, and enters an inlet 232 of the compressor 204. Optionally, the refrigerant passes through one or more fluidic components prior to reaching the inlet 232 of the compressor 204. For example, the one or more fluidic components may include, but are not limited to, at least one transducer 234 (e.g., a temperature transducer, a pressure transducer, etc.), at least one valve 236, and/or a filter. For instance, the at least one valve 236 may include, but is not limited to, a service valve.

After being pressurized by the compressor 204, the refrigerant in gaseous form exits the compressor 204 via outlet 238 of a check valve 240 and enters an inlet 242 of the condenser 202. For example, at least a portion of the refrigerant may be routed to an inlet 244 of the evaporator 200, instead of to the inlet 242 of the condenser 202. Optionally, the refrigerant passes through one or more additional fluidic components prior to reaching the inlet 242 of the condenser 202 and/or the inlet 244 of the evaporator 200. For example, the one or more fluidic components may include, but are not limited to, at least one transducer 246 (e.g., a temperature transducer, a pressure transducer, etc.), at least one valve, and/or a filter.

In some configurations, a portion of the refrigerant passes through at least one control valve 248. Gaseous refrigerant may be provided through a control valve 248 fluidically coupled to the outlet 238 of the compressor 204 and the inlet 244 of the evaporator 200. Here, the control valve 248 may create a gaseous refrigerant loop through the evaporator 200 and the compressor 204, providing a false load to keep the compressor 204 running under low load conditions.

The refrigerant then circulates in liquid form between an outlet 250 of the condenser 202 and the inlet 244 of the evaporator 200. After passing through a receiver 252 (e.g., a filter or drier in line with the refrigerant flow, a reservoir or tank, or the like), the refrigerant (e.g., a liquid portion) is routed through an expansion valve 254 to reduce the temperature of the refrigerant prior to entering the inlet 244 of the evaporator 200. For example, the receiver 252 may be configured to separate liquid refrigerant from gaseous or vapor refrigerant, which is generally in equilibrium within the receiver 252. For instance, there may be more vapor when the pressure is higher within the receiver 252, as compared to there being more liquid when the pressure is lower within the receiver 252.

Alternatively or in addition, at least a portion of the refrigerant may be optionally routed to an inlet 256 of the compressor 204 (e.g., including optionally through or past a sight glass 258), instead of to the inlet 244 of the evaporator 200, for the purpose of cooling the compressor 204. Optionally, the refrigerant passes through one or more additional fluidic components prior to reaching the inlet 244 of the evaporator 200. For example, the one or more fluidic components may include, but are not limited to, at least one transducer (e.g., a temperature transducer, a pressure transducer, etc.), at least one valve 260, and/or a filter.

In contrast to the known configuration shown in FIG. 2, FIG. 3 illustrates the improved zone chiller 118B of the system 100, in accordance with one or more embodiments of the present disclosure. The zone chiller 118B includes an evaporator 300, a condenser 302, and a compressor 304 in fluidic communication therebetween. It should be understood that embodiments directed to the zone chiller 118B and the portion of the system 100 in FIG. 3 are interchangeable with embodiments directed to the zone chiller 118 and the system 100 of FIG. 1, and vice versa, unless otherwise noted.

In embodiments, primary coolant from the primary coolant supplies 104A, 104B is provided to an inlet 306 of the zone chiller 118B. The inlet 306 of the zone chiller 118B is in fluid communication with an inlet 308 of the evaporator 300 and an inlet 310 of the condenser 302. For example, coolant may flow through a flow control valve 311 prior to reaching the inlet 310 of the condenser 302. Optionally, the primary coolant passes through one or more additional fluidic components prior to reaching the inlet 308 of the evaporator 300 and/or the inlet 310 of the condenser 302. For example, the one or more fluidic components may include, but are not limited to, at least one strainer 312, at least one transducer 314 (e.g., a temperature transducer, a pressure transducer, etc.), at least one valve 316, and/or a filter. For instance, the at least one valve 216 may include, but is not limited to, a relief valve.

In embodiments, an outlet 318 of the evaporator 300 is fluidically coupled to an outlet 320 of the zone chiller 118B, which in turn is fluidically coupled to the zone coolant supply 120A, 120B for the one or more air-cooling components 124. Optionally, zone coolant from the evaporator 300 passes through one or more fluidic components prior to reaching the outlet 320 of the zone chiller 118B. For example, the one or more fluidic components may include, but are not limited to, at least one transducer 321 (e.g., a temperature transducer, a pressure transducer, etc.), at least one valve, and/or a filter.

It is noted that the primary coolant from the primary coolant supplies 104A, 104B that enters the inlet 308 of the evaporator 300 becomes the zone coolant that exits the outlet 318 of the evaporator 300 (and the outlet 320 of the zone chiller 118B) for the zone coolant supplies 120A, 120B. Although the temperature of the primary coolant is adjusted (e.g., lowered) by the operation of the evaporator 300, the same coolant flows through the evaporator 300 between the inlet 308 and the outlet 318.

In embodiments, the zone coolant return 122A, 122B is in fluid communication with an inlet 322 of the zone chiller 118B. The inlet 322 of the zone chiller 118B is in fluid communication with the inlet 310 of the condenser 302, such that the zone coolant from the zone coolant return 122A, 122B mixes with the primary coolant from the primary coolant supply 104A, 104B, including through a flow control valve 311. In this regard, primary coolant from the primary coolant supplies 104A, 104B, and return coolant from the zone coolant return 122A, 122B, is provided in series before the inlet 310 of the condenser 302. The mixing of the returned coolant and the coolant supply before the inlet 310 of the condenser 302 in the zone chiller 118B is beneficial because the flow rate through the zone chiller 118B is reduced, by optimizing flow through the condenser 302.

It is noted that the zone coolant from the zone coolant return 122A, 122B is the same coolant as the primary coolant from the primary coolant supply 104A, 104B, although the temperature of the coolant may be adjusted by the mixing of the primary coolant with the returned zone coolant prior to entering the inlet 310 of the condenser 302. For example, mixing the two coolants prior to the condenser 302 may reduce the temperature of the coolant being input into the condenser 302 at the inlet 310 (e.g., from the zone coolant return 122A, 122B). It is noted that the mixture of the two coolants may be controlled by the flow control valve 311, including optionally being automatically (or substantially automatically) controlled based on observed temperature of the coolant along the flow line in the zone chiller 118B from at least some of one or more transducers 314, 328, 334, 346.

An outlet 324 of the condenser 302 is fluidically coupled to an outlet 326 of the zone chiller 118B, which in turn is fluidically coupled to the primary coolant return 106A, 106B for the system 100. Optionally, the coolant passes through one or more fluidic components prior to reaching the or the outlet 326 of the zone chiller 118B. For example, the one or more fluidic components may include, but are not limited to, at least one transducer 328 (e.g., a temperature transducer, a pressure transducer, etc.), at least one valve, and/or a filter.

In embodiments, one or more of the inlets 306, 322 and/or the outlets 320, 326 of the zone chiller 118B may include or be coupled to respective expansion joints 327 prior to being in fluid communication with a respective coolant supply 104A, 104B, 120A, 120B or respective coolant return 106A, 106B, 122A, 122B. Alternatively or in addition, one or more of the inlets 306, 322 and/or the outlets 320, 326 of the zone chiller 118B may be coupled to at least one respective valve 329 (e.g., a butterfly valve, etc.), where the at least one respective valve 329 is in fluid communication with a respective coolant supply 104A, 104B, 120A, 120B or respective coolant return 106A, 106B, 122A, 122B.

In embodiments, a refrigerant circulates in a loop between the evaporator 300 and the condenser 302. The refrigerant transitions between gaseous and liquid form during circulation, transferring heat between coolant from the primary coolant supply 104A, 104B passing through the evaporator 300 between the inlet 308 and the outlet 318 and refrigerant from the primary coolant supply 104 passing through the condenser 302.

The refrigerant exits an outlet 330 of the evaporator 300 in gaseous form after heat is transferred from the coolant received from the primary coolant supply 104A, 104B to the refrigerant to cool the coolant, and enters an inlet 332 of the compressor 304. Optionally, the refrigerant passes through one or more fluidic components prior to reaching the inlet 332 of the compressor 304. For example, the one or more fluidic components may include, but are not limited to, at least one transducer 334 (e.g., a temperature transducer, a pressure transducer, etc.), at least one valve 336, and/or a filter.

After being pressurized by the compressor 304, the refrigerant in gaseous form exits the compressor 304 via an outlet 338 of a check valve 340 and enters an inlet 342 of the condenser 302. For example, at least a portion of the refrigerant (e.g., a liquid portion) may be routed to an inlet 344 of the evaporator 300, instead of to the inlet 342 of the condenser 302. Optionally, the refrigerant passes through one or more additional fluidic components prior to reaching the inlet 342 of the condenser 302 and/or the inlet 344 of the evaporator 300. For example, the one or more fluidic components may include, but are not limited to, at least one transducer 346 (e.g., a temperature transducer, a pressure transducer, etc.), at least one valve 348, and/or a filter.

The refrigerant then circulates in liquid form between an outlet 350 of the condenser 302 and the inlet 344 of the evaporator 300. After passing through a receiver 352 (e.g., a filter or drier in line with the refrigerant flow, a reservoir or tank, or the like), the refrigerant (e.g., a liquid portion) is routed through an expansion valve 354 to reduce the temperature of the refrigerant prior to entering the inlet 344 of the evaporator 300. For example, the receiver 352 may be configured to separate liquid refrigerant from gaseous or vapor refrigerant, which is generally in equilibrium within the receiver 352. For instance, there may be more vapor when the pressure is higher within the receiver 352, as compared to there being more liquid when the pressure is lower within the receiver 352.

Alternatively or in addition, at least a portion of the refrigerant may be optionally routed to an inlet 356 of the compressor 304 (e.g., including optionally through or past a sight glass 358), instead of to the inlet 344 of the evaporator 200, for the purpose of cooling the compressor 304. Optionally, the refrigerant passes through one or more additional fluidic components prior to reaching the inlet 344 of the evaporator 300. For example, the one or more fluidic components may include, but are not limited to, at least one transducer (e.g., a temperature transducer, a pressure transducer, etc.), at least one valve 360, and/or a filter 361.

In embodiments, gaseous refrigerant may be provided through a load-balancing valve 362 fluidically coupled to the outlet 338 of the compressor 304 and the inlet 344 of the evaporator 300. Here, the load-balancing valve 362 may create a gaseous refrigerant loop through the evaporator 300 and the compressor 304, providing a false load to keep the compressor 304 running under low load conditions.

Referring generally to FIGS. 1 and 3, in one non-limiting example the one or more outdoor chillers 102, the one or more coolant distribution units 108, and the one or more zone chillers 118A, 118B circulate the primary coolant, with the primary coolant within the primary coolant supply 104A, 104B being at a range of operating temperatures between approximately 80° F. and 90° F. and the primary coolant within the primary coolant return 106A, 106B being at a range of operating temperatures between approximately 100° F. and 110° F. In addition, the one or more coolant distribution units 108 and the one or more liquid-cooled components 114 circulate the secondary coolant, with the secondary coolant within the secondary coolant supply 110 being at a range of operating temperatures between approximately 80° F. and 90° F. and the second coolant within the secondary coolant return 112 being at a range of operating temperatures between approximately 100° F. and 110° F. Further, the one or more zone chillers 118B and the one or more air-cooling components 124 circulate coolant, with the coolant within the zone coolant supply 120A, 120B being at a range of operating temperatures between approximately 55° F. and 65° F., and the coolant within the zone coolant return 122A, 122B being at a range of operating temperatures between approximately 85° F. and 95° F.

For purposes of the present disclosure, any of the valves of the zone chiller 118B may include, but are not limited to, a check valve, a water valve, a gas bypass valve, an expansion valve, a flow control valve, a load-balancing valve, a pressure relief valve, a filling ball valve, a stop valve, a bleed valve, or injection valve or inlet port, a drain valve or outlet port, or the like without departing from the scope of the present disclosure.

It should be understood that the fluidic connections between the various components of the system 100, including within the zone chiller 118B, may include conduits formed from a material that is generally non-reactive to the coolant or refrigerant. It is noted that lack of reactivity between the coolant or refrigerant and the conduits may be desirable to prevent a reduction of system operations and/or failure of system of operations due to blockage and/or rupture. For example, the conduits may be piping or tubing fabricated from a heat-or corrosion-resistant metal including, but not limited to, stainless steel (e.g., SS 316, or the like). By way of another example, the conduits may be piping or tubing fabricated from a heat-or corrosion-resistant material including, but not limited to, a flexible or rigid plastic or rubber material such as an ethylene propylene diene monomer (EPDM) or another suitable elastomer.

Although embodiments in FIG. 3 are directed to circulating the primary coolant through the condenser 302 and the evaporator 300 of the zone chiller 118B, it is contemplated that the zone chiller 118B may include an isolated pumping system similar to the isolated system for the secondary coolant through the one or more coolant distribution units 108 and the liquid-cooled components 114. With an isolated supply system, the supply coolant from the outdoor chiller 102 only flows to the condenser 302 of the zone chiller 118B and the zone chiller 118B has independent chilled coolant through the evaporator 300, without departing from the scope of the present disclosure.

In the system 100, the temperatures of the coolant flow and the operation of the various components that receive or provide the coolant at those various temperatures may be balanced to reduce power consumption and increase efficiency gains for only liquid-cooling components, only air-cooled components, and/or a combination of liquid-cooled and air-cooled components.

For example, a system 100 with only liquid-cooled components 114 (and optional coolant distribution units 108) has a range of operating temperatures for the coolant in the primary coolant supply between approximately 80° F. and 90° F., which may be accomplished by the outdoor chillers 102. Efficiency gains are observed in terms of power consumption by the outdoor chillers 102, and in terms of the necessary backup power that may be required for the system 100 to meet code requirements. In some cases, peak power with backup systems may be 20%-30% lower with only liquid-cooled components 114. In general, where a cooler temperature supply coolant is only required in limited amounts (e.g., due to the percentage of air-cooling components 124 within the system 100 being low or zero), the outdoor chillers 102 can output higher coolant temperatures with a higher coefficient of performance (COP) and more free-cooling hours.

However, where the system 100 has a combination of liquid-cooled components 114 and air-cooling components 124, different ranges of operating temperatures are required. Removing the zone chillers 118B while still including air-cooling components 124 would require utilizing the outdoor chillers 102 to reduce the temperature of the coolant to the range of operating temperatures for the air-cooling components 124 (e.g., approximately 60° F.). This would unnecessarily increase the power consumption throughout the system 100, despite the lower range of operating temperatures not being necessary for the one or more coolant distribution units 108 in fluid communication with the one or more liquid-cooled components 114.

Thus, including the zone chillers 118B in the system 100 allows for the outdoor chillers 102 to only reduce the range of operating temperatures for the coolant in the primary coolant supply 104 to between approximately 80° F. and 90° F., which is acceptable to the coolant distribution units 108 for the liquid-cooled components 114. The zone chillers 118B further reduce the temperature of the coolant supplied to the air-cooling components 124 to a range of operating temperatures between approximately 55° F. and 65° F., moving a portion of power consumption needs from the global outdoor chillers 102 to the localized zone chillers 118B.

With the initial addition of zone chillers 118B into the system 100, efficiency gains are observed as less power consumption occurs by the outdoor chillers 102. For example, 80% liquid-cooled components 114 using primary coolant at approximately 85° F. and 20% air-cooling components 124 using zone coolant at approximately 65° F. results in dramatically lower peak power consumption, as compared to dropping the primary coolant to approximately 65° F. throughout the entire system 100.

However, efficiency gains may be reduced as additional zone chillers 118B and/or air-cooling components 124 are added to the system 100. In some cases, including where the percentage of air-cooling components 124 increases to (nearly) 100% meaning (almost) no liquid-cooled components 114 (e.g., either installed, or at least in operation), it may be beneficial to cool the primary supply coolant 104 to approximately 65° F. throughout the entire system 100 with the outdoor chillers 102, instead of using the zone chillers 118 to make incremental changes in the temperature of the primary coolant from the outdoor chillers 102 to the air-cooling components 124. Where the supply coolant is sufficiently reduced in temperature to be usable directly by the air-cooling components 124, the supply coolant may pass directly through the zone chiller 118B without further adjustment (or the zone chillers 118B may be bypassed, or removed entirely, from the system 100).

In embodiments, the system 100 is capable of monitoring the power consumption throughout the entire system 100, and determine the appropriate temperature to cool the primary coolant supply 104. The system 100 is also able to adapt in response to observed changes in power consumption, and modify the operation of the outdoor chillers 102 and/or the zone chillers 118B.

For example, adaptation may occur in the addition or removal of components from within the system 100 including, but not limited to, coolant distribution units 108, liquid-cooled components 114, zone chillers 118B, and/or air-cooling components 124. To accomplish this, the system 100 should be understood as being controllable with respect to the usage of the zone chillers 118B to implement the incremental temperature adjustment between the outdoor chillers 102 and the air-cooling components 124. By way of another example, one or more operational parameters of the system 100 may be adjusted based on observed data related to temperature, pressure, power consumption, and the like.

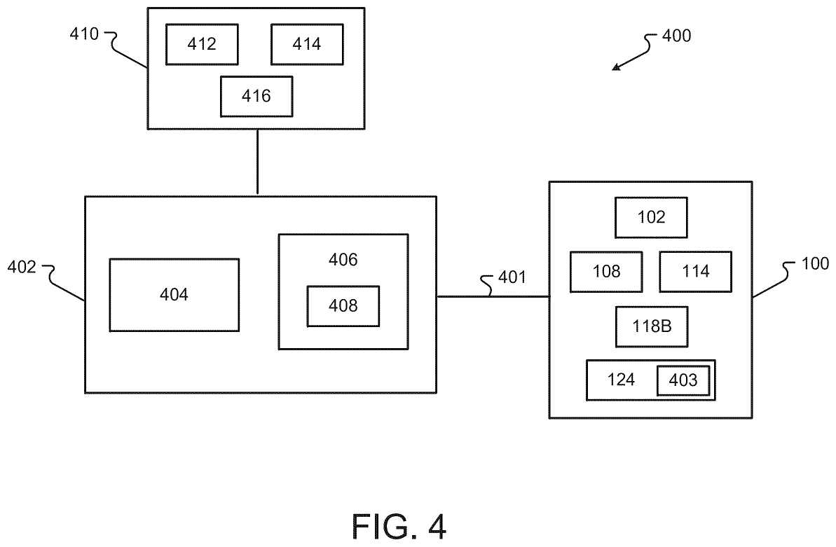

FIG. 4 illustrates a control system 400 including (or separate from but in communication with) the system 100 for multistage high-efficiency cooling, in accordance with one or more embodiments of the present disclosure. It should be understood that embodiments directed to the assemblies, subassemblies, and/or components of the system 100 from FIG. 1, including the zone chiller 118B from FIG. 3, may be applicable to the system 100 in FIG. 4 and vice versa unless otherwise noted.

The control system 400 includes one or more control units 402 (e.g., a controller, server, or the like) in communication with components of the system 100. It should be understood that the one or more control units 402 may be a component of the system 100, or may be a separate component in communication with the system 100, without departing from the scope of the present disclosure. For example, the control units 402 may acquire data 401 from transducers 314, 321, 328, 334, 346 within the zone chiller 118B. More generally, the control units 402 may acquire data from elements including, but not limited to, sensors within the outdoor chillers 102, the coolant distribution units 108, the liquid-cooled components 114, the zone chillers 118B, the air-cooling components 124 (and corresponding components 403 being air-cooled), the coolant supplies 104A, 104B, 110, 120A, 120B, and/or the coolant returns 106A, 106B, 112, 122A, 122B.

Where relative humidity is taken into consideration, one operational parameter to be monitored includes dew point protection. In the control system 400, for example, dew point protection is provided by one or more of: (1) Real-Time Monitoring, by measuring data hall air humidity levels and dew point in real time, (2) Dynamic Adjustments, by actively adjusting the water temperature supply based on dew point calculations to prevent condensation rather than relying on pre-set limits, and (3) Integrated Controls, or the using of sensors and controls to coordinate cooling operations with humidity levels, ensuring optimal performance without manual interventions. Additionally or alternatively, the foregoing is provided with a manual override, such as to override automatic (or substantially automatic) operation, such as during construction or other events when the building envelope for the data center has not been enclosed.

In general, the one or more control units 402 may include one or more processors 404 and memory 406 (e.g., a memory medium, memory device, non-transitory computer readable medium, or the like). The one or more processors 404 may be configured to execute program instructions 408 maintained on or stored in the memory 406. The one or more processors 404 of the one or more control units 402 may execute any of the various method or process steps necessary to operate the system 100, and/or the subassemblies and/or components of the system 100. In this regard, at least a portion of the disclosure may be understood as being directed to a computer-implemented method, as at least a portion of the disclosure may be understood as being directed to a computer-implemented invention.

In embodiments, control system 400 may include a user interface 410 coupled (e.g., physically coupled, electrically coupled, communicatively coupled, or the like) to the one or more control units 402. For example, the user interface 410 may be a separate device coupled to the one or more control units 402. By way of another example, the user interface 410 and the one or more control units 402 may be located within a common or shared housing.

In embodiments, the user interface 410 may include one or more displays 412 and/or one or more user input devices 414. Where communication is wired, the user interface 410 may include one or more port connectors 416 (e.g., for the transmitting and/or receiving of power and/or data, and the like).

The control system 400 may include one or more sensors coupled (e.g., physically coupled, electrically coupled, communicatively coupled, or the like) to or integrated in the one or more control units 402, the system 100, and/or the subassemblies and/or components of the system 100. The one or more sensors may be operable to determine various operational, physical, and/or environmental parameters of the system 100, the subassemblies and/or components of the system 100, and/or the control system 400; the environment surrounding the system 100, the subassemblies and/or components of the system 100, and/or the control system 400; and the like. For instance, the sensors may be operable to determine the power consumption of the system 100, the subassemblies and/or components of the system 100, and/or the control system 400.

The control system 400 may include one or more transmitters and/or receivers coupled (e.g., physically coupled, electrically coupled, communicatively coupled, or the like) to or integrated in the one or more control units 402, the system 100, and/or the subassemblies and/or components of the system 100. The one or more transmitters and/or receivers may be configured to transmit data 401 and/or receive data 401 for the system 100 and/or the subassemblies and/or components of the system 100 (e.g., from sensors installed within the system 100 and/or the subassemblies and/or components of the system 100) or from external third-party control units (e.g., controllers, servers, or the like) either via wired connections or wireless connections, which may be configured as transmitting (Tx) units, receiving (Rx) units, or combination Tx/Rx units.

The control system 400 may be configured to monitor the system 100 and/or the subassemblies and/or components of the system 100 via received and/or transmitted data. The control system 400 may be configured to generate control signals to adjust one or more components of the system 100 and/or the subassemblies and/or components of the system 100 via a feedback loop or a feed forward loop based on the received and/or transmitted data, either automatically (or substantially automatically) or following an input from a user. The control system 400 may be configured to receive and/or transmit data in a standardized format and/or a non-standardized format. Where the data is in a non-standardized format, the data may be converted to a standardized format upon receipt and/or prior to transmission to sensors, third-party control units, or the like.

In some configurations, automation and artificial intelligence may be provided to (or within) the control system 400. The control system 400 can incorporate predictive analytics (e.g., forecasting outdoor temperatures and load profiles) to enhance energy efficiency and reduce manual intervention.

In one non-limiting example, the control unit 402 may acquire data about the power consumption for various components of the system 100 and/or about the temperature or pressure of coolant circulating through the system 100. Based on that acquired data, the control unit may adjust valves or other devices within the system 100 capable of modifying fluid flow.

For example, the control unit 402 may adjust the temperature of coolant being provided by the one or more outdoor chillers 102 to the one or more coolant distribution units 108 and the one or more zone chillers 118B to reduce power consumption by utilizing the incremental change in coolant temperature afforded by the zone chillers 118B.

By way of another example, where a high percentage of air-cooling is being utilized, the control unit 402 may adjust the temperature of coolant being provided by the one or more outdoor chillers 102 to the one or more coolant distribution units 108 and the one or more zone chillers 118B to reduce power consumption by not utilizing the one or more zone chillers 118B and instead passing already-cooled coolant through the one or more zone chillers 118B.

By way of another example, the control unit 402 may optimize power consumption based on the ambient environment temperature and the percentage of liquid-cooling versus percentage of air-cooling utilized within a data center. This optimization may take into consideration the temperature of the primary coolant supply, including where the coolant is water from a primary main supplied to a structure housing the data center. Based on this optimization, the control unit 402 may optionally utilize only free-cooling by the outdoor chillers 102, instead of utilizing the zone chillers 118B to reduce the operating temperature of the liquid coolant for the air-cooling components 124.

Although embodiments of the present disclosure are directed to automatic or semi-automatic control of the various components within the system 100 by the control unit 402, it is contemplated that one or more of the operation or adjustment of components of the system 100 may be performed manually by an operator, either in addition to or instead of automatically or semi-automatically by the control unit 402, without departing from the scope of the present disclosure.

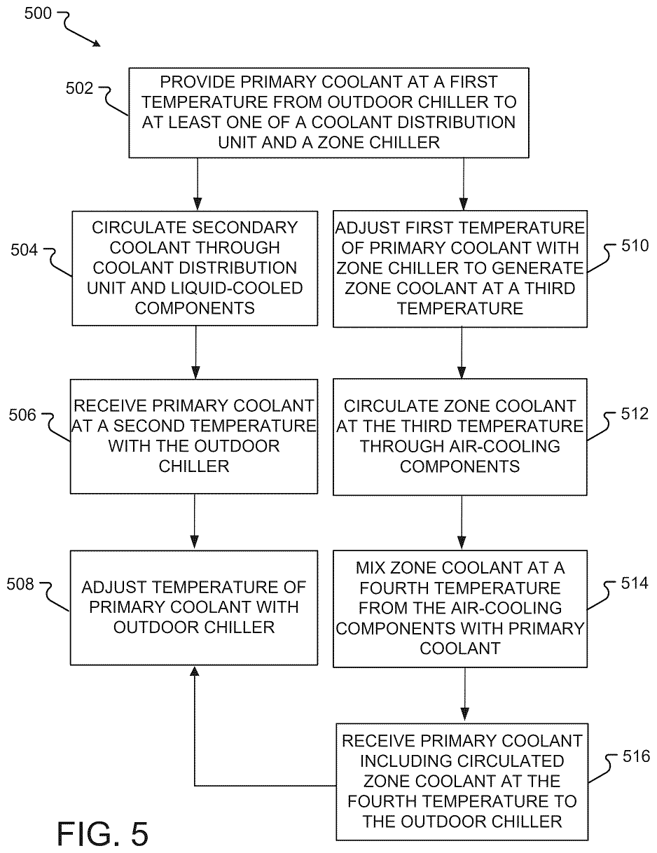

FIG. 5 is a flow diagram of a method or process 500 respectively illustrating the operation the system 100 for high-efficiency cooling, in accordance with one or more embodiments of the present disclosure. While a general order for the actions of the method or process 500 is shown in FIG. 5, the method or process 500 can include more or fewer actions or can arrange the order of the actions differently (including simultaneously, substantially simultaneously, or sequentially) than those shown in FIG. 5. It is noted that the method or process 500 shall be explained with reference to the components, devices, subassemblies, environments, etc. described in conjunction with FIGS. 1, 3, and 4. For example, it is noted that the embodiments as illustrated in FIGS. 1, 3, and 4 should be understood as being directed to the embodiments described with respect to FIG. 5, and vice versa, without departing from the scope of the present disclosure.

In embodiments, a primary coolant is provided 502 at a first temperature from an outdoor chiller to at least one of a coolant distribution unit and a zone chiller. Where the system 100 includes both liquid-cooled components 114 and air-cooling components 124 for air-cooled components 403, one or more outdoor chillers 102 are in fluid communication with and circulates primary coolant at a first temperature to one or more coolant distribution units 108 (e.g., for the liquid-cooled components 114) and one or more zone chillers 118B (e.g., for the air-cooling components 124 and air-cooled components 403) via at least one primary coolant supply 104.

In embodiments, a secondary coolant is circulated 504 through the coolant distribution unit and liquid-cooled components. The coolant distribution unit 108 transfers heat between the primary coolant supplied via the primary coolant supply 104 and the secondary coolant. The secondary coolant is provided via the secondary coolant supply 110 to the liquid-cooled components 114 at a first temperature, and the secondary coolant is returned via the secondary coolant return 112 to the coolant distribution unit 108 at a second temperature. For example, the second temperature is higher than the first temperature, as heat is transferred from the liquid-cooled components 114 to the secondary coolant.

In embodiments, the primary coolant is received 506 at a second temperature by the outdoor chiller. The one or more outdoor chillers 102 are in fluid communication with and receive primary coolant at a second temperature from the one or more coolant distribution units 108 via at least one primary coolant return 106. For example, the second temperature may be greater than the first temperature, as heat is transferred from the secondary coolant to the primary coolant within the one or more coolant distribution units 108.

In embodiments, the temperature of the primary coolant is adjusted 508 with the outdoor chiller. Where the second temperature is different from the first temperature, the outdoor chiller adjusts (e.g., cools) the primary coolant to be the first temperature prior to re-circulation to at least one of the coolant distribution unit 108 and the zone chiller 118B.

In embodiments, the first temperature of the primary coolant is adjusted 510 with a zone chiller to generate zone coolant at a third temperature. The primary coolant at the first temperature passes through the zone chiller 118B, includes an evaporator 300, a condenser 302, and a compressor 304. Refrigerant circulating through the zone chiller 118B adjusts (e.g., lowers) the first temperature of the primary coolant to be a third temperature, to be provided as a zone coolant via at least one zone coolant supply 120 to one or more air-cooling components 124. In this regard, the zone chiller 118B operates as an incremental stage for cooling the coolant from the outdoor chillers 102, instead of the outdoor chillers 102 having to cool to a temperature needed for the operation of air-cooling components 124.

In embodiments, the zone coolant is circulated 512 through air-cooling components. The zone coolant is circulated through the air-cooling components 124 via the at least one zone coolant supply 120 and zone coolant return 122, where heat is transferred from the air to the zone coolant by the air-cooling components 124 to adjust (e.g., increase) the temperature of the zone coolant to a fourth temperature.

In embodiments, the zone coolant at a fourth temperature from the air-cooling components is mixed 514 with primary coolant. As illustrated in FIG. 3, the zone coolant return 122 mixes with primary coolant prior to the primary coolant passing through the condenser 202 and before the primary coolant passes through the zone chiller 118B to the at least one primary coolant return 106.

In embodiments, the primary coolant including zone coolant at the fourth temperature is received 516 by the outdoor chiller. The one or more outdoor chillers 102 are in fluid communication with and receive primary coolant including zone coolant at the fourth temperature from the one or more zone chillers 118B via at least one primary coolant return 106.

Where the fourth temperature of the received primary coolant and zone coolant is different from the first temperature, the outdoor chiller adjusts the primary coolant and zone coolant to be the first temperature prior to re-circulation to at least one of the coolant distribution unit 108 and the zone chiller 118B. For example, the temperature of the returned primary coolant may be different (e.g., greater) than the first temperature, as the return primary coolant is mixed with zone coolant at the fourth temperature which may be greater than the first temperature.

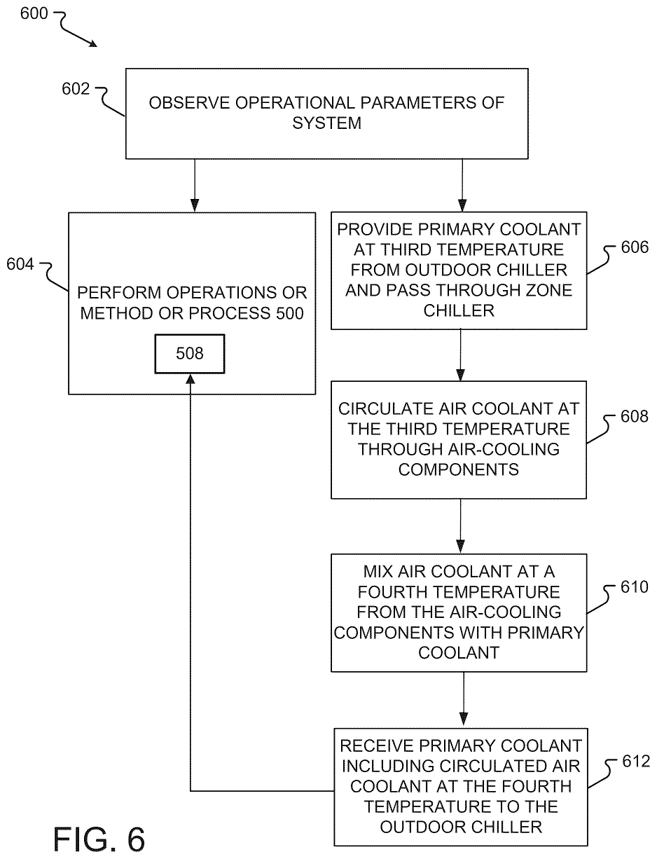

FIG. 6 is a flow diagram of a method or process 600 respectively illustrating the operation the system 100 for high-efficiency cooling, in accordance with one or more embodiments of the present disclosure. While a general order for the actions of the method or process 600 is shown in FIG. 6, the method or process 600 can include more or fewer actions or can arrange the order of the actions differently (including simultaneously, substantially simultaneously, or sequentially) than those shown in FIG. 6. It is noted that the method or process 600 shall be explained with reference to the components, devices, subassemblies, environments, etc. described in conjunction with FIGS. 1, 3, and 4. For example, it is noted that the embodiments as illustrated in FIGS. 1, 3, and 4, and FIG. 5, should be understood as being directed to the embodiments described with respect to FIG. 6, and vice versa, without departing from the scope of the present disclosure.

In embodiments, operational parameters of the system are observed 602. Operational parameters including, but not limited to, coolant temperature, coolant pressure, power consumption, ambient temperature, and the like are observed in the system 100, including optionally by a control unit 402 in communication with the system 100.

In embodiments, one or more operations of the method or process 500 are performed 604. Where a determination is made that power consumption would be reduced by utilizing the incremental temperature adjustment via the zone chillers 118B (e.g., with a certain percentage of both liquid-cooling and air-cooling being in use within the system 100), one or more operations of the method or process 500 are performed. In particular, a first temperature for coolant is set by the outdoor chillers 102, which is increased during circulation of the coolant through the one or more coolant distribution units 108 to a second temperature that is greater than the first temperature before being again cooled by the outdoor chiller 102. In addition, a third temperature that is less than the first temperature for primary coolant to generate zone coolant is set by the zone chillers 118B, and which is then increased during circulation of the zone coolant through the one or more air-cooling components 124 to a fourth temperature before being circulated back to the outdoor chiller 102 to be again cooled by the outdoor chiller 102.

In embodiments, the outdoor chillers provide 606 the primary coolant at a third temperature which passes through the zone chillers. Where a determination is made that power consumption would be reduced by providing the primary coolant at the lower temperature for air-cooling components 124 (e.g., with a considerable percentage of air-cooling being in use within the system 100), the outdoor chillers 102 may instead be set to cool the primary coolant to the third temperature for the air-cooling components 124 without activating compressors 304 in the zone chillers 118B. As the primary coolant is already the lower third temperature, the system 100 does not need to utilize the incremental stages of the zone chiller 118B. As such, the primary coolant can pass through (or bypass) the zone chillers 118B without further temperature adjustment, with the temperature for the primary coolant remaining substantially equivalent both prior to entering and after exiting the evaporator 300 as the refrigerant is not circulated to transfer heat from the primary coolant received by the evaporator 300 to the primary coolant received by the condenser 302.

It is noted that the primary coolant at the third temperature would also be supplied to any liquid-cooled components 114 (and/or intervening coolant distribution units 108) within the system 100, in addition to being provided to the zone chillers 118B.

In embodiments, the zone coolant is circulated 608 through air-cooling components. The zone coolant is circulated through the air-cooling components 124 via the at least one zone coolant supply 120 and zone coolant return 122, where heat is transferred from the air to the zone coolant by the air-cooling components 124 to adjust (e.g., increase) the temperature of the zone coolant to a fourth temperature.

In embodiments, the zone coolant at a fourth temperature from the air-cooling components is mixed 610 with primary coolant. As illustrated in FIG. 3, the zone coolant return 122 mixes with primary coolant prior to the primary coolant passing through the condenser 202 and before the primary coolant passes through the zone chiller 118B to the at least one primary coolant return 106.

In embodiments, the primary coolant including zone coolant at the fourth temperature is received 612 by the outdoor chiller. The one or more outdoor chillers 102 are in fluid communication with and receive primary coolant including zone coolant at the fourth temperature from the one or more zone chillers 118B via at least one primary coolant return 106.

Where the fourth temperature of the received primary coolant and zone coolant is different from the first temperature, the outdoor chiller adjusts the primary coolant and zone coolant to be the first temperature prior to re-circulation to at least one of the coolant distribution unit 108 and the zone chiller 118B. For example, the temperature of the returned primary coolant may be different (e.g., greater) than the first temperature, as the return primary coolant is mixed with zone coolant at the fourth temperature which may be greater than the first temperature.

In this regard, where both liquid-cooled and air cooled-components are installed within the system 100, including in pre-determined percentages, increasing efficiency of power consumption in respective flow circuits may occur by utilizing multiple coolant temperatures between outdoor chillers 102, coolant distribution units 108 for liquid-cooled components 114, and air-cooling components 124. Incremental adjustment of the coolant temperatures for the air-cooling components 124 occurs using zone chillers 118B, from higher temperatures supplied to coolant distribution units 108 for the liquid-cooled components 114 to lower temperatures necessary for the air-cooling components 124.

However, the percentages for air-cooling may shift closer to predominantly seeing power loads for air cooling, either with the installation of additional air-cooled components into the system 100 and/or the removal or shutdown of liquid-cooled components of system 100. When this occurs, to increase efficiency of power consumption in respective flow circuits it may be desirable to instead reduce the temperature of the coolant throughout the entire system 100 with the outdoor chillers 102 to be the necessary temperatures for the air-cooling components 124, instead of utilizing the incremental stages through the zone chillers 118B.

The control system 400 may monitor this change and make determinations about whether to adjust the coolant temperatures through the system 100 accordingly. This monitoring may occur either automatically (or substantially automatically), or alongside a user with prompts or manual override controls, including to determine what operational parameters of the system 100 would provide the highest efficiency (e.g., as determined, non-limitingly, by power consumption within the system 100), and optionally adjust the system accordingly.

Advantages of the present disclosure include a multistage high-efficiency cooling system. The multistage high-efficiency cooling system includes outdoor chillers that are thermally coupled to liquid-cooled components, including optionally through intervening coolant distribution units. The outdoor chillers are thermally coupled to air-cooling components through indoor or zone chillers, where the air-cooling components provided air conditioning for air-cooled components.

Advantages of the present disclosure include a control system for monitoring and adjusting the operation of the multistage high-efficiency cooling system. In some configurations, primary coolant is supplied by the outdoor chillers to the coolant distribution units (or the liquid-cooled components, directly) and additionally to the indoor or zone chillers at a first temperature. The indoor or zone chillers adjust the temperature of the primary coolant to a second temperature prior to the primary coolant reaching the air-cooling components. In other configurations, primary coolant is supplied by the outdoor chillers to the coolant distribution units (or the liquid-cooled components, directly) and additionally to the indoor or zone chillers at a temperature required by the air-cooling components, but which can also be utilized by the coolant distribution units (or the liquid-cooled components, directly).

Advantages of the present disclosure include a method of operating the multistage high-efficiency cooling system. Advantages of the present disclosure include a method of monitoring and adjusting the operation of the multistage high-efficiency cooling system. In one non-limiting example, advantages of the present disclosure are directed to the optimizing of power consumption based on the ambient environment temperature and the percentage of liquid-cooling versus percentage of air-cooling utilized within a data center, which may take into consideration the temperature of the primary coolant supply including where the coolant is water from the primary main supplied to a data center structure, including optionally to utilize free-cooling by the outdoor chillers in place of the indoor or zone chillers to reduce the operating temperature of the liquid coolant for the air-cooling components.

Although embodiments of the present disclosure are directed to implementation of the systems and method described herein in data centers, it should be understood such is merely illustrative as is not intended on being limited to the present disclosure. In general, the present disclosure may be understood as being directed to any application that may monitor coolant temperature and power consumption to increase efficiency, including implementing multiple incremental stages of adjustment for the coolant temperature throughout a circulation system with liquid-cooled and/or air-cooled loads.

What is claimed is:

1. A zone chiller for a multistage high-efficiency cooling system, comprising:
an evaporator that receives primary coolant from a primary coolant supply via a first inlet at a first temperature and provides zone coolant via a first outlet at a second temperature to a zone coolant supply;
a condenser that receives primary coolant from the primary coolant supply in a first inlet at the first temperature, wherein the primary coolant is provided in series with and controllably mixable with zone coolant received from a zone coolant return at a third temperature prior to the first inlet of the condenser, and wherein the primary coolant is provided via a first outlet of the condenser to a primary coolant return; and
a compressor able to circulate refrigerant from a second outlet of the evaporator to a second inlet of the condenser, and from a second outlet of the condenser to a second inlet of the evaporator, to form a refrigerant loop between the evaporator, the compressor, and the condenser.

2. The zone chiller of claim 1, wherein when the compressor is activated to circulate the refrigerant, heat is transferred from the primary coolant received by the first inlet of the evaporator to the primary coolant received by the first inlet of the condenser, the second temperature is less than the first temperature, and the third temperature is greater than the second temperature.

3. The zone chiller of claim 1, wherein when the compressor is not activated to circulate the refrigerant, heat is not transferred from the primary coolant received by the first inlet of the evaporator to the primary coolant received by the first inlet of the condenser, the second temperature is substantially equivalent to the first temperature, and the third temperature is greater than the second temperature.

4. The zone chiller of claim 1, further comprising a flow control valve for the primary coolant prior to the first inlet of the condenser, wherein the flow control valve controls a flow of primary coolant from the primary coolant supply to the first inlet of the condenser prior to the mixing of the zone coolant with the primary coolant.

5. The zone chiller of claim 1, further comprising one or more temperature transducers to monitor at least one of coolant temperature and refrigerant temperature within the zone chiller.

6. The zone chiller of claim 1, further comprising one or more pressure transducers to monitor at least one of coolant pressure and refrigerant pressure within the zone chiller.

7. The zone chiller of claim 1, further comprising:
a receiver able to receive the refrigerant circulated in a liquid state from the second outlet of the condenser; and
an expansion valve able to receive the refrigerant circulated in the liquid state from the receiver and able to provide the refrigerant circulated in the liquid state to the second inlet of the evaporator.

8. The zone chiller of claim 1, further comprising
a load-balancing valve in fluidic communication with the compressor and the second inlet of the evaporator, wherein the load-balancing valve provides refrigerant from the compressor to the second inlet of the evaporator instead of the refrigerant provided from the second outlet of the condenser to the second inlet of the evaporator.

9. The zone chiller of claim 1, wherein at least a portion of the refrigerant is provided from the second outlet of the condenser to the compressor for compressor cooling.

10. A multistage high-efficiency cooling system, comprising:
an outdoor chiller in fluidic communication with a primary coolant supply and a primary coolant return, wherein the outdoor chiller provides primary coolant at a first temperature via the primary coolant supply; and
a zone chiller in fluidic communication with the primary coolant supply and the primary coolant return, the zone chiller comprising:
an evaporator that receives primary coolant from the primary coolant supply via a first inlet at a first temperature and provides zone coolant via a first outlet at a second temperature to a zone coolant supply;
a condenser that receives primary coolant from the primary coolant supply in a first inlet at the first temperature, wherein the primary coolant is provided in series with and controllably mixable with zone coolant received from a zone coolant return at a third temperature prior to the first inlet of the condenser, and wherein the primary coolant is provided via a first outlet of the condenser to a primary coolant return; and
a compressor able to circulate refrigerant from a second outlet of the evaporator to a second inlet of the condenser, and from a second outlet of the condenser to a second inlet of the evaporator, to form a refrigerant loop between the evaporator, the compressor, and the condenser.

11. The multistage high-efficiency cooling system of claim 10, further comprising:
an air-cooling component in fluidic communication with the zone coolant supply and the zone coolant return, wherein the air-cooling component is located proximate to an air-cooled component, and wherein circulated air transfers heat to the zone coolant to change the zone coolant from the second temperature to the third temperature.

12. The multistage high-efficiency cooling system of claim 11, wherein the air-cooled component is a server, a server rack, or a server cabinet.

13. The multistage high-efficiency cooling system of claim 10, wherein when the compressor is activated to circulate the refrigerant, heat is transferred from the primary coolant received by the first inlet of the evaporator to the primary coolant received by the first inlet of the condenser, the second temperature is less than the first temperature, and the third temperature is greater than the second temperature.

14. The multistage high-efficiency cooling system of claim 10, wherein when the compressor is not activated to circulate the refrigerant, heat is not transferred from the primary coolant received by the first inlet of the evaporator to the primary coolant received by the first inlet of the condenser, the second temperature is substantially equivalent to the first temperature, and the third temperature is greater than the second temperature.

15. The multistage high-efficiency cooling system of claim 10, further comprising:
a coolant distribution unit in fluidic communication with a secondary coolant supply and a secondary coolant return and in fluidic communication with the primary coolant supply and the primary coolant return; and
a liquid-cooled component in fluidic communication with the secondary coolant supply and the secondary coolant return.

16. The multistage high-efficiency cooling system of claim 15, wherein the coolant distribution unit receives primary coolant from the primary coolant supply at the first temperature and provides the primary coolant to the primary coolant return at a fourth temperature.

17. The multistage high-efficiency cooling system of claim 15, wherein the liquid-cooled component is a server, a server rack, or a server cabinet.

18. A method of operating a zone chiller for a multistage high-efficiency cooling system, the method comprising:
receiving primary coolant at a first temperature from a primary coolant supply with a first inlet of an evaporator;
receiving primary coolant at the first temperature from the primary coolant supply with a first inlet of a condenser;
providing zone coolant at a second temperature via a first outlet of the evaporator to a zone coolant supply;
receiving zone coolant via the first inlet of the condenser at a third temperature, wherein the primary coolant is provided in series with and controllably mixable with the zone coolant received from a zone coolant return at the third temperature prior to the first inlet of the condenser; and
providing primary coolant controllably mixed with returned zone coolant via a first outlet of the condenser to a primary coolant return,
wherein the evaporator and the condenser are within a refrigerant loop with a compressor able to circulate refrigerant from a second outlet of the evaporator to a second inlet of the condenser, and from a second outlet of the condenser to a second inlet of the evaporator.

19. The method of claim 18, wherein when the compressor is activated to circulate the refrigerant, heat is transferred from the primary coolant received by the first inlet of the evaporator to the primary coolant received by the first inlet of the condenser, the second temperature is less than the first temperature, and the third temperature is greater than the second temperature.

20. The method of claim 18, wherein when the compressor is not activated to circulate the refrigerant, heat is not transferred from the primary coolant received by the first inlet of the evaporator to the primary coolant received by the first inlet of the condenser, the second temperature is substantially equivalent to the first temperature, and the third temperature is greater than the second temperature.
